(19) United States
(12) Patent Application Publication
(10) Pub. No.: US 2003/0007176 A1
(43) Pub. Date: Jan. 9, 2003

(54) Image output device, connecting destination selecting method and image output system

(75) Inventor: Kouichi Takamine, Hyogo-Ken (JP)

Correspondence Address: McDERMOTT, WILL & EMERY, 600 13th Street, N.W., Washington, DC, 20005-3096, US

(73) Assignee: Matsushita Electric Industrial Co., Ltd.

(21) Appl. No.: 10/189,557

(22) Filed: Jul. 8, 2002

(30) Foreign Application Priority Data
Jul. 9, 2001 (JP) 2001-208039

(51) Int. Cl. G06F 3/12; G06F 3/00; G06F 13/00; G06F 15/16; H04B 5/00; H05K 11/00

(52) U.S. Cl. 358/1.15; 710/40; 709/227; 709/240; 455/41; 455/344

(57) ABSTRACT

To Provide an image output device capable of performing an optimal data output operation (especially a print operation). A precondition is an image output device outputting data from external equipment establishing multichannel connection therewith. Check means checks an existing connection state when receiving a new connection request from an external equipment piece. Connection means secures a connection channel with the external equipment piece having issued the new connection request on the basis of a result of the checking attained by the check means. With such a construction, in the present invention, print data from an external equipment piece having issued a new connection request takes a priority in handling over that from an external equipment piece connected through a channel having a small usage frequency.

### BACKGROUND OF THE INVENTION

1. Field of the Invention

The present invention relates to an image output device outputting data from external equipment establishing multichannel connection therewith.

2. Description of the Related Art

Along with progresses in digital technique and network technology, popularization has occurred in mutual connection between a personal computer and its peripheral equipment on a network. Moreover, in recent years, cases have been frequently encountered where a single piece of equipment connected to a network is shared by plural pieces of equipment on the network.

As a single equipment piece shared by plural equipment pieces, there is typically shown a network printer having a network I/F. That is, by registering a network printer individually with personal computers connected to a network, the plural personal computers can share the printer therebetween.

Meanwhile, most recently, there has been progressive spread of a technique connecting mutually a personal computer and its peripheral equipment pieces on a wireless network because of freedom from easy inclination to complexity of a wire network in cable wiring therefor.

In this case, as shown in FIG. 11A, a print server 400, which performs all needs of printing, generally is provided between each of the personal computers 100 to 300 and an image output device (printer) 500. That is, the print server 400 receives print data from the personal computers 100 to 300 and holds the print data temporarily to thereafter, send the print data in the order of reception to the image output device 500. With such a configuration equipped with the print server 400, there is an advantage that each personal computer 100, 200 or 300 can start another operation immediately after the personal computer 100, 200 or 300 passes the print data to the print sever 400.

Note that, as shown in FIG. 11B, with a configuration equipped with a router 800 instead of the print server 400 as well, a similar effect can be attained if the router 800 have a function holding data temporarily.

In the mean time, the wireless network technology has been received attention even in a home in company with popularization of the internet. At present, as representatives of in-home wireless networks, there can be exemplified: a network of Bluetooth specification, wireless 1394: a wireless version of IEEE std 1394 (IEEE: The Institute of Electrical and Electronics Engineers, Inc.) and others.

Consideration being here given to a way of use of a printer in a future home, it would be expected that a printer is used by not only a personal computer but also a portable telephone, a digital camera, in addition home appliances such as a television set and so on. Furthermore, a configuration would be expected that print data is sent directly to a printer from each of equipment pieces with no installation of the printer server 400, which has heretofore provided interposing therebetween.

Under such circumstances, plural external equipment pieces (including various kinds of equipment) can establish multichannel connection with a printer. For example, not only a television set is connected to a printer using a channel, but a personal computer can also be connected to the printer using another channel.

However, that external equipment can be thus connected to a printer requires is realized in an environment, as a precondition, where a free channel is available when the external equipment issues a connection request to the printer. That is, according to a conventional art, a connection request issued from external equipment when no free channel is available can not be accepted on the printer side.

A case also exists, however, where though a channel is secured, no substantially meaningful communication takes place between an external equipment piece using the channel and a printer. While in such a case, it is expected to be beneficial that connection with an external equipment piece having issued a new connection request takes a priority over the existing connection with the external equipment piece, no method to determine which one has a superiority to the other was established in a convention art.

In an aspect other than whether or not a channel could be secured, the following problem still existed unsolved in a conventional art.

That is, according to the conventional art, print data was processed simply in order of reception thereof on the side of a printer. However, in an environment where plural external equipment pieces can be connected to a printer through multiple channels, it is not proper to perform a print operation in such a procedure.

There is, for example, a case where data received by a portable telephone is required to be printed without a delay. In such a case, according to the conventional art, the data from the portable telephone cannot be printed till after data from a television set not required to be printed especially in haste is processed to the full on the printer side if the data from a television set is in process when the portable telephone receives the data.

Such a problem occurs without limiting to a scene where plural external equipment pieces establish multichannel connection with a printer. That is, in a case where a single external equipment piece is connected to a printer through multiple channels as well, the problem described above arises if plural connection requests are issued from the single external equipment piece.

### SUMMARY OF THE INVENTION

The present invention has been proposed on the basis of the conventional circumstances and it is an object of the present invention to provide an image output device capable of optimally performing an output operation (especially a print operation) of data.

The present invention, in order to achieve the above object, adopts the following means in an image output device outputting data from external equipment establishing multichannel connection therewith.

That is, check means checks an existing connection state when receiving a new connection request from an external equipment piece. Connection means secures a connection channel with the external equipment piece having issued the new connection request on the basis of a result of the checking attained by the check means. More specifically, the connection means secures the connection channel with the external equipment piece having issued the new connection request by cutting off connection of a channel having a small usage frequency, or by alternatively reducing a data transfer rate of a channel having a small usage frequency.

In the present invention, print data from an external equipment piece having issued a new connection request takes a priority in handling over that from an external equipment piece connected through a channel having a small usage frequency.

On the other hand, comparison means compares a priority of a job relating to a first channel and a priority of a job relating to a second channel with each other when receiving a new connection request from an external equipment piece. The connection means changes the order of jobs on the basis of a result of the comparison obtained by the comparison means. More specifically, the connection means changes at least one of the order of data reception, a data transfer rate and the order of data spooling on the basis of a result of the comparison obtained by the comparison means.

In such a manner, in the present invention, the order of data reception is determined on the basis of priority information attached to a connection request. By doing so, needless to say that data is sequentially printed in the decreasing order of a priority starting with data with the highest priority.

### BRIEF DESCRIPTION OF THE DRAWINGS

FIG. 1 is a functional block diagram of an image output system in first to fourth embodiments;

FIG. 2 is a functional block diagram of an image output system in a fifth embodiment;

FIG. 3 is a flow chart showing operations of the image output system in the first embodiment;

FIG. 4 is a flow chart showing operations of the image output system in the first embodiment;

FIG. 5 is a flow chart showing operations of the image output system in the second embodiment;

FIG. 6 is a flow chart showing operations of the image output system in the second embodiment;

FIG. 7 is a flow chart showing operations of the image output system in the second embodiment;

FIG. 8 is a flow chart showing operations of the image output system in the third embodiment;

FIG. 9 is a flow chart showing operations of the image output system in the fourth embodiment;

FIGS. 10A to 10C are diagrams showing waveforms and spectra of a typical digital modulation scheme; and

FIGS. 11A and 11B are representations for describing a conventional image output system.

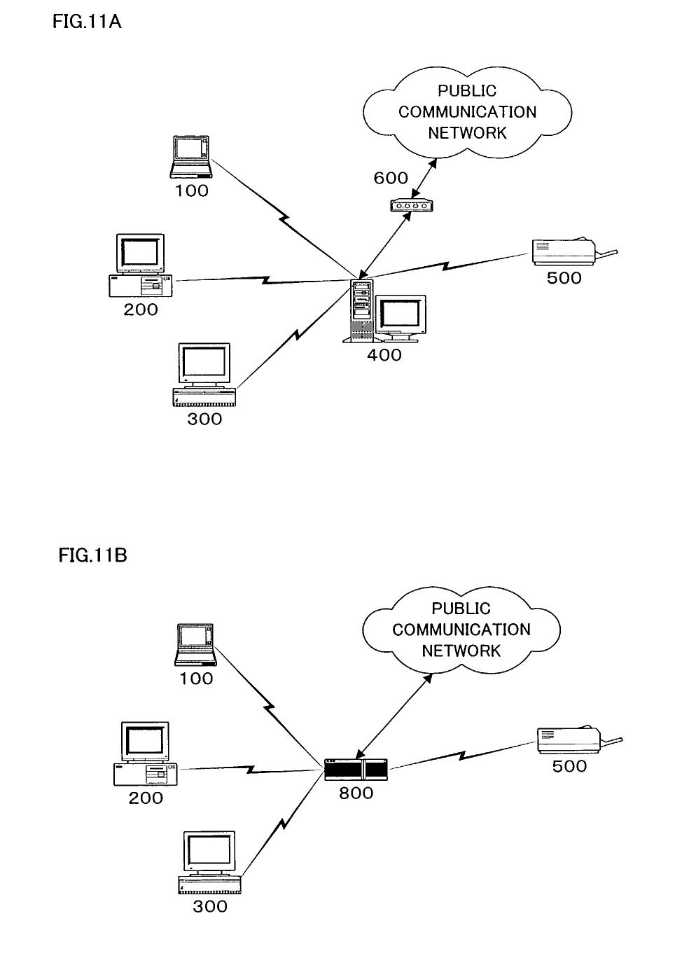

### DESCRIPTION OF THE PREFERRED EMBODIMENTS

Detailed description will be given of embodiments of the present invention below according to the accompanying drawings.

First Embodiment

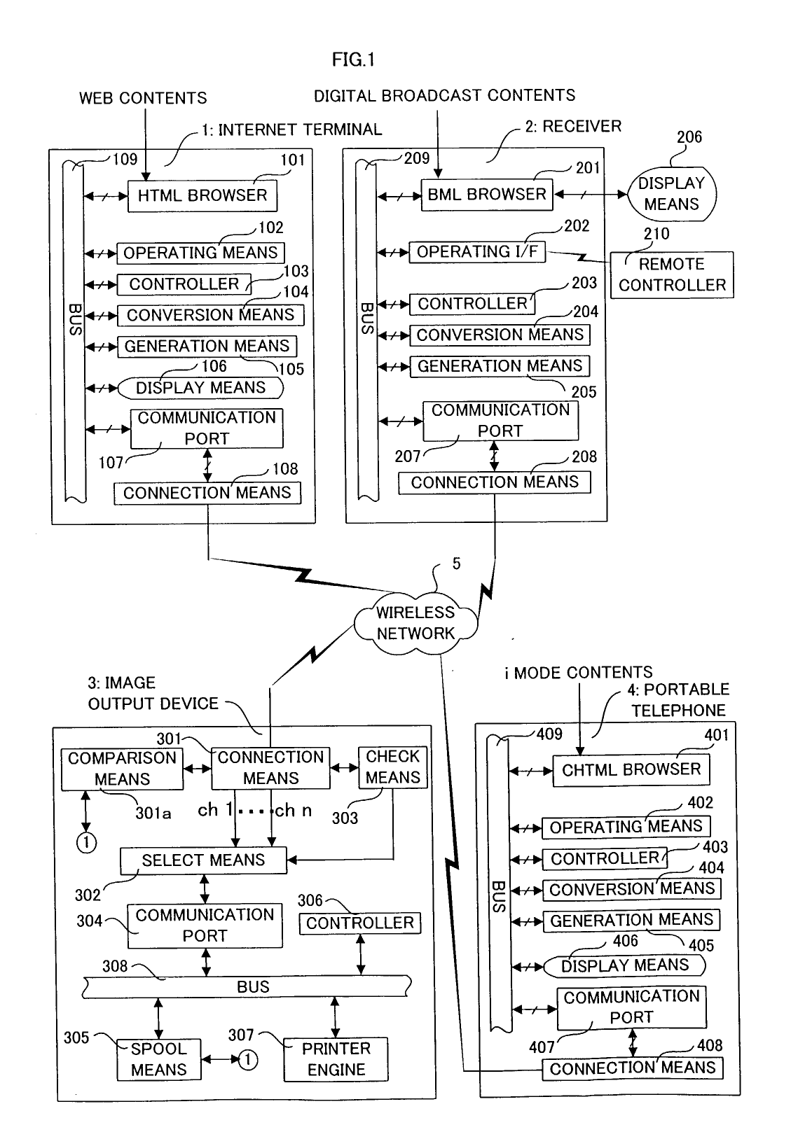

In this embodiment, as shown in FIG. 1, an image output system is taken up in which an internet terminal 1, a receiver 2, a portable telephone 4 and an image output device 3 are connected to mutually via a wireless network 5 such as wireless LAN or a Bluetooth network.

The internet terminal 1 is a terminal capable of receiving and reading contents described in HTLM, such as a personal computer equipped with a HTLM (Hyper Text Markup Language) browser. Such a terminal can be realized by mutually connecting means described below with a bus 109.

That is, a HTLM browser 101 displays WEB contents received from the internet on display means 106 such as a display. A controller 103 receives an instruction from operating means 102 such as a keyboard to control of an operation of the internet terminal 1. Conversion means 104 converts WEB contents from the HTML browser 101 in HTML to those in an intermediate language such as Java. Generation means 105 generates data for printing on the basis of data from the conversion means 104. A communication port 107 is connected to a wireless network 5 via the connection means 108 and has a function to transmit print data from the generation means 105 to the image output device 3 together with a connection request.

The receiver 2 is a receiver capable of receiving contents described in BML (Broadcast Markup Language) from a broadcast station to read such as a set top box. Such a receiver can be realized by mutually connecting means described blow with a bus 209.

That is, a BML browser 201 displays digital broadcast contents received from a broadcast station on display means 206 such as a television set. A controller 203 receives an instruction from a remote control 210 via an operating interface 202 to control an operation of the receiver 1. Conversion means 204 converts digital broadcast contents from the BML browser 201 in BML to those in an intermediate language such as Java. Generation means 205 generates data for printing on the basis of data from the conversion means 204. A communication port 207 is connected to the wireless network 5 via connection means 208 and has a function to transmit print data from the generation means 205 to the image output device 3 together with a connection request.

The portable telephone 4 is a portable telephone capable of receiving contents described in CHTML (Compact Hyper Text Markup Language) from the internet to read, such as a portable telephone capable of using an i mode. Such a portable telephone can be realized by mutually connecting means described blow with a bus 409.

That is, a CHTML browser 401 displays i mode contents received from the internet on display means 406 such as a display. A controller 403 receives an instruction from operating means 402 such as a button to control an operation of the portable telephone 4. Conversion means 404 converts i mode contents from the CHTML browser 401 in CHTML to those in an intermediate language such as Java. Generation means 405 generates data for printing on the basis of data from the conversion means 404. A communication port 407 is connected to the wireless network 5 via connection means 408 and has a function to transmit print data from the generation means 405 to the image output device 3 together with a connection request.

Description will be given of a construction of the image output device 3 having received the connection request, together with operations thereof. Note that in the following description, equipment other than the image output device 3, that is the internet terminal 1, the receiver 2 and the portable telephone 4 are collectively referred to as “external equipment.”

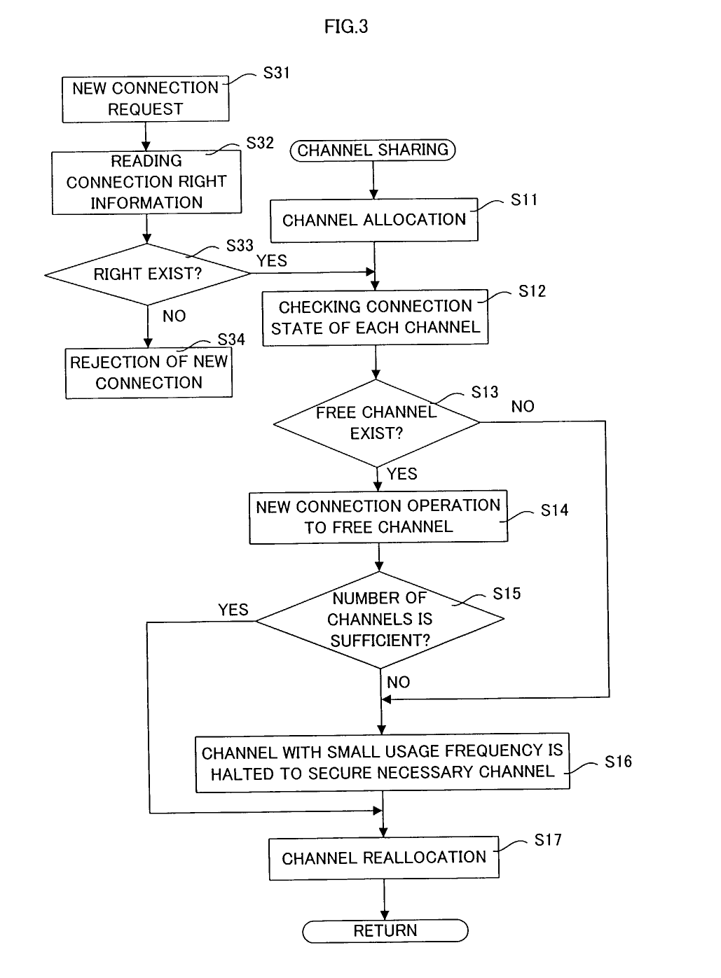

At first, connection means 301 allocates channels to the external equipment connected thereto via the wireless network 5 (FIG. 3, step S11). While there exists an operation called “channel sharing” prior to the channel allocation operation (FIG. 3, step S11), the operation of channel sharing is an operation only to share channels in one way or another, such as to restore a channel allocation state in the previous run, which has no direct relation to the present invention.

The connection means 301 here, when receiving a new connection request, reads connection right information attached to the connection request. Then, the connection means 301 determines whether or not external equipment having issued the connection request has a right to be connected to the image output device 3 on the basis of the connection right information that the connection means 301 has thus read (FIG. 3, step S31→step S32→step S33).

While there is no specific limitation to of what nature information is adopted as the connection right information, an ID unique to each piece of external equipment belonging to the system (which is hereinafter referred to as a “machine ID”) is preferably adopted as the connection right information, as described below.

That is, the connection means 301, in a case where a machine ID attached to a connection request is a registered machine ID, determines that the external equipment having issued the connection request has a right to be connected to the image output device 3 (FIG. 3, Yes in step S33). On the other hand, the connection means 301, in a case where a machine ID attached to a connection request is a non-registered machine ID, determines that the external equipment having issued the connection request has no right to be connected to the image output device 3 to reject the connection request (FIG. 3, No in step S33).

In order that the connection means 301 performs the determination, it is true, the communication means 301 or means capable of communicating with the connection means 301 has to grasp a machine ID of external equipment having a right to be connected to the image output device 3. Since such an ID management technique has been widely known, however, no detailed description will be given here.

As information that can be adopted as connection right information other than a machine ID, there can be exemplified an ID unique to each of users belonging to the system (which is hereinafter referred as a “user ID”). In this case, the user preferably inputs a user ID of its own from the operating means 102 or the like each time the user issues a print request (hereinafter, a “print request” and a “connection request” are used without especially discriminating one from the other) from external equipment.

Meanwhile, check means 303 checks connection states of each channel allocated by the connection means 301 at prescribed intervals. The check means 303 determines whether or not a free channel exists on the basis of a result of the checking to notify the connection means 301 and the select means 302 of a result of the determination (FIG. 3, step S12→step S13).

Information of which the check means 303 notifies the connection means 301 and others is not limited to the result of determination (that is, information indicating whether or not a free channel exists). For example, the result of checking, which is base information for the determination, (that is, information indicating a connection state of each channel) may be alternatively notified, thereby enabling determination on whether or not a free channel exists in the connection means 301 and others, which are destinations of notification.

Further detailed description will be given of an operation when the determination result is notified to the connection means 301 below.

At first, the check means 303, when determining that a free channel exists, gives a channel number of the free channel to the connection means 301. With this, the connection means 301 performs a new connection operation to the free channel, that is allocation of the free channel to the external equipment piece having issued a new connection request as described above (FIG. 3, Yes in step S13→step S14).

On the other hand, the check means 303, when determining that no free channel exists, designates the channel with the smallest usage frequency among allocated channels by the connection means 301 as described above to give a channel number of the designated channel number to the connection means 301. With this, the connection means 301 causes a channel with the channel number to be in a halt state (that is connection relating to the channel number is cut off) to thereby, secure a connection channel with the external equipment piece having issued a new connection request as described above. Then, the thus secured channel is reallocated to the external equipment piece (FIG. 3. No in step S13→step S16→step S17).

Under a situation where plural connection requests have been accepted, there is a chance to be short of channels in order to meet a required number in allocating free channels to external equipment pieces having issued the connection requests (FIG. 3, step S14→No in step S15). In such a case, by causing the channel with the smallest usage frequency to be in a halt state, securing is achieved of a connection channel with external equipment having issued a new connection request. Then, the channel secured in this way is reallocated to the external equipment (FIG. 3, No in step S15→step S16→step S17).

In the description so far, the term of “secure or securing” is used to express acquirement of a state in which a channel can be newly allocated by causing a channel to be in a halt state. In some passages of the following description, however, the term of “secure or securing” is used for the term of “allocation” without especially discriminating one from the other and vice versa.

As described above, a connection channel with an external equipment piece having issued a new connection request (the channel number is hereinafter referred to as “channel 1 for convenience of description) is allocated by the connection means 301. When the channel 1 is connected to the communication port 304 by the select means 302, print data is inputted to the spool means 305 via the communication port 304 and the bus 308.

The spool means 305 is means for spooling print data into a printer engine 307 from the connection means 301. That is, the spool means is means in which a high speed auxiliary storage is used as a buffer, and thereby, for enabling continuation of printing without a delay.

The printer engine 307 is means for printing print data from the spool means 305. As print schemes adopted by the printer engine 307, there have been available various types such as a thermal transfer scheme (a sublimation type and a heat melting type), a thermosensible scheme, an ink jet scheme, an electrophotographic scheme and others without no limitation to a specific one thereof.

As seen from the above description, print data inputted to the spool means 305 via the communication port 304 and the bus 308 is spooled by the spool means 305 and thereafter printed by the printer engine 307. That is, in the present invention, print data from an external equipment piece having issued a new connection request is handled with a priority taken over printed data from an external equipment piece connected to a channel with a small usage frequency.

Such a construction would be thought not to be reasonable at first glance since printing is not performed in the order of reception of connection requests. If consideration is given of a low possibility of substantially meaningful communication performed by a channel with a small usage frequency, it is beneficial that connection with an external equipment piece having issued a new connection takes a priority over the connection with an external equipment with a small usage frequency.

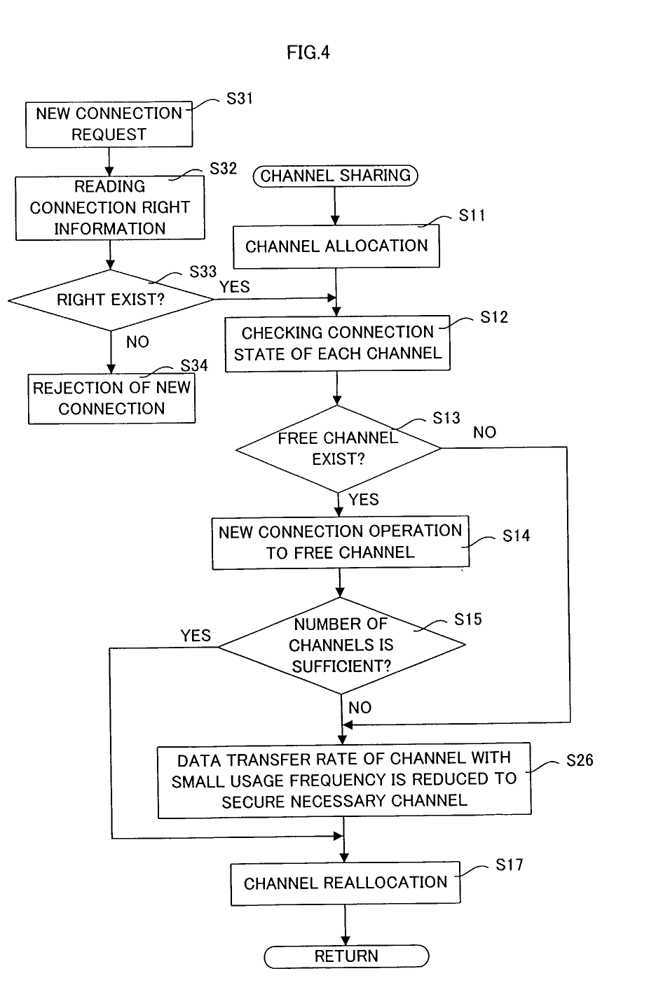

Even in such a scene, it is not always necessary to cause a channel with a small usage frequency to be in a halt state. That is, a data transfer rate in a channel with a small usage frequency is reduced, thereby also enabling securing of a connection channel with an external equipment having issued a new connection request (FIG. 4, step S26).

The application scope of the present invention is not limited to a scene where plural equipment pieces establish multichannel connection with the image output device 3. That is, in a scene where a single external equipment piece is connected with the image output device 3 through multiple channels as well, plural connection requests are, in a case, issued from the single external equipment piece; therefore, there is found a value of the present invention applied to the scene.

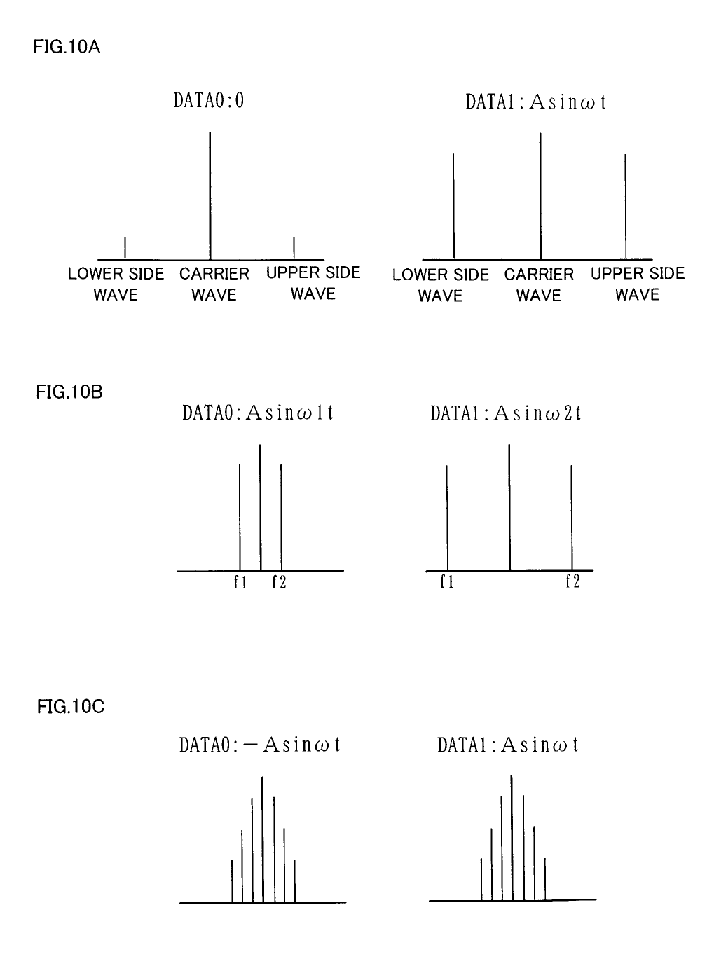

For the purpose of realizing an errorless digital information transmission, in a case of establishing a multiconnection between the external equipment and the image output device 3 via the wireless network, it is preferable to limit its connection channel. Next, description relating to the above will be given in detail. In FIGS. 10A, 10B and 10C, here are shown waveforms and spectra of typical digital modulation schemes.

FIG. 10A is a diagram showing a waveform and spectrum of ASK (Amplified Shift Keying) digital modulation scheme in which an information bit is expressed by a magnitude, large or small, or the presence or absence of an amplitude of a sine wave.

FIG. 10B is a diagram showing a waveform and spectrum of FSK (Frequency Shift Keying) digital modulation scheme in which an information bit is expressed by a magnitude, large or small, of a frequency of a sine wave.

FIG. 10C is a diagram showing a waveform and spectrum of PSK (Phase Shift Keying) digital modulation scheme in which an information bit is expressed by a phase of a sine wave.

As seen from the figures, a necessity arises for a spectral width to some extent. A spectral width occupied by one channel is called an occupied bandwidth and the occupied bandwidth is dependent on a speed of information to be transmitted, that is a transmission information quantity per a unit time (in a unit of bps).

In a case where AM modulation is performed with an analog signal, a necessity arises for a bandwidth twice times the maximum frequency of speech to be transmitted. For example, in order to transmit a frequency (of sound) as high as 1.5 kHz, an occupied bandwidth of 3 kHz is required. In order to transmit a frequency (of sound) as high as 15 kHz, an occupied bandwidth of 30 kHz is required.

This shows that up to a high frequency can be transmitted with a wide occupied bandwidth. That is, it is understood that a higher sound quality can be transmitted with a wider occupied bandwidth. Putting aside characteristics of noise such as white noise and pink noise, an FM radio using a wider band is better in an analog sound quality than an AM radio with a narrower occupied bandwidth, which is fundamentally based on this principle.

Shanon's theorem on communication (channel) capacity is thought out by application of the relationship between an occupied bandwidth and an analog sound quality to a digital sound system. According to the theorem, as shown in an equation 1, with an occupied bandwidth W[Hz] given, a communication capacity C [bps] of digital information transmissible without error can be obtained from a ratio of a signal power S[W] to a noise power N[W] in the band. Contrary to this, the lowest necessary bandwidth W[Hz] for transmission can also be obtained from a ratio of a signal power S[W] to a noise power N[W] and a communication capacity C[bps].

C=W log 2 (1+S/N) (1)

In digital transmission, the above described “sound quality” is replaced with a “communication capacity (information speed).” Thereby, it is found that since information can be transmitted at a higher speed with increase in communication capacity, digital image and sound qualities are improved, while a wider occupied bandwidth is necessary. While the equation 1 is a logical expression, a working environment can be closer to that of the thorem with contrivance in various ways even at the current technological levels.

As seen from the communication capacity theorem, in broadband communication schemes such as of spread spectrum (CDMA) and a multicarrier, a high speed information communication line (capacity) can be secured instead of a necessity for a wide occupied bandwidth. Note that a spread spectrum communication scheme is a communication scheme in which in order to transmit information, information is spread over a frequency band much wider than the lowest necessary band.

A study is conducted on a communication capacity C with a signal power S and a noise power N as variables in regard to the above thorem. For example, a case is considered where a receive environment is as good as that a signal power S is received at a value 63 times as strong as a noise power N; as seen from an equation 2, C=6W is obtained, leading to understanding that a communication capacity 6 times as large as W can be secured with the same occupied bandwidth adopted.

C=W log 2 (1+63) (2)

Contrary to this , in a bad environment in which a signal power S is very week, a ratio of a signal power S/a noise power N approaches to 0 to give the following equation 3. That is in such an environment, C=0W, therefore, it is expected to lose the merit of broadband communication.

C=W log 2 (1+0) (3)

In a noise environment at up to some level of noise power, however, it is expected that digital information transmission without error can be possible by reducing a communication capacity even if a ratio of a signal power S/a noise power N is poor, though by a little (that is, even if a ratio of a signal power S/a noise power N does not show a so high value). This is a ground that spread spectrum communication is generally said to be strong against noise.

As described above, in an environment with a poor ratio of a signal power S/a noise power N, digital information transmission without error can be realized with a reduced communication capacity. That is, in an environment with a poor ratio of a signal power S/a noise power N, preferably, the number of channels to be connected is limited.

Second Embodiment

Description will be given of the second embodiment below limiting to different points from the first embodiment.

In this embodiment, it is a precondition that priority information is attached to a connection request. The priority information is information expressing a priority of a job to be processed on the side of the image output device 3 and in the following description, it is assumed that priorities of “00”, “01”, “10” and “11” are decreasingly lower in the order; with the first place takes the highest priority.

That is, the connection means 301 having received a connection request Ra from an external equipment piece a, a connection request Rb from an external equipment piece b and a connection request Rc from an external equipment piece c allocates channels to the external equipment pieces a to c. The “allocation” performed here is a necessary operation for obtaining priority information and in the actual sense of the word, could be expressed “provisional allocation.”

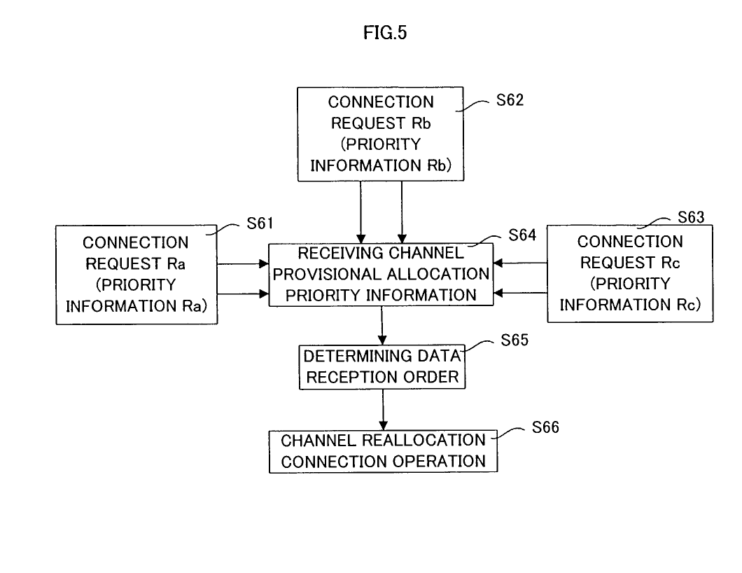

Then, the connection means 301 reads individually priority information attached to the connection requests Ra to Rc to give the priority information to the comparison means 301a. With the priority information given, the comparison means 301a compares the priority information with each other to return a result of the comparison to the connection means 301. Then, the connection means 301 determines data receive order on the basis of the comparison result. (FIG. 5, step S61, step S62 and step S63→step S64→step S65).

That is, when the priority information attached to the connection request Ra is “10”, the priority information attached to the connection request Rb is “01” and the priority information attached to the connection request Rc is “00”, the connection means 301 determines acceptance of the connection requests Rc, Rb and Ra in the order. Channels are reallocated to the external equipment pieces a to c in the order of reception determined in such a way to start a connection operation (FIG. 5, step S66).

In the present invention, as described above, the order of data reception is determined on the basis of priority information attached to connection requests. In such a procedure adopted, needless to say that printing is performed sequentially from data with the highest priority to data with a lower priority.

While in the above description, an operation comparing priorities of jobs relating to the new connection requests is exemplified when plural new connection requests are received, the present invention is not limited thereto. An operation may be performed, for example, in which when a new connection request is received, a priority relating to the new connection request is compared with a priority relating to an existing connection request.

That is, in the present invention, when a new connection request (or plural new requests) is received, a priority of a job relating to a first channel and a priority of a job relating to a second channel are compared with each other. It is natural that the first and second channels are different from each other.

While it is here expressed that “a priority of a job relating to a first channel and a priority of a job relating to a second channel are compared with each other,” if an operation to compare priorities of two jobs with each other is repeated, priorities of three or more jobs can also be compared with each other, That is, the present invention can be applied in a scene where three or more jobs are objects for comparison of priorities.

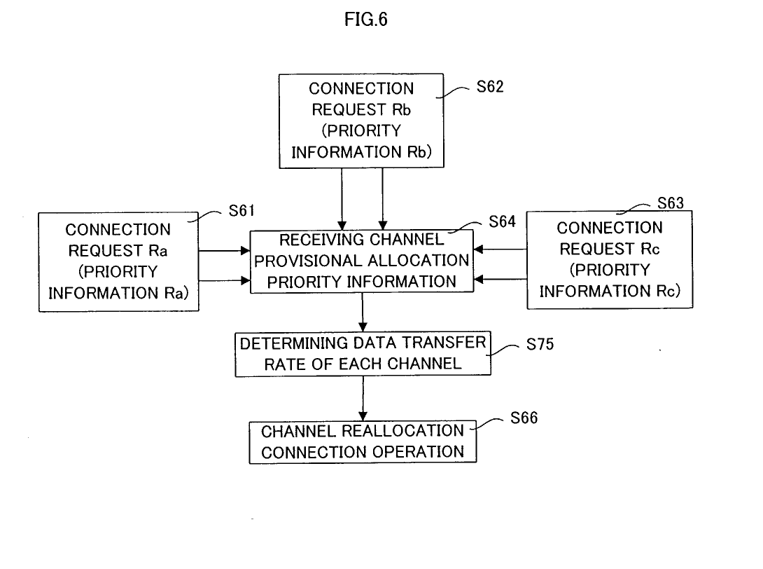

Items to be determined on the basis of priority information are not limited to the order of data reception. For example, data transfer rates of respective channels can be determined on the basis of priority information (FIG. 6, step S75).

That is, in a case where priority information attached to a connection request Ra is “10”, priority information attached to a connection request Rb is “01” and priority information attached to a connection request Rc is “00”, the connection means 301 is to determine data transfer rates so as to decrease sequentially in the order of the connection requests Rc, Rb and Ra with the first place having the highest value. With such transfer rates in the decreasing order, there can be enjoyed an effect of performing printing starting with data with the highest priority, followed by data with a lower priority and in addition, an effect of enabling transferring data with a higher priority at a faster speed with more of certainty.

According to the first embodiment, data inputted to the spool means 305 from the connection means 301 is spooled in the order of inputting, followed by transmission to the printer engine 307. However, a construction in which spooling is performed to the spool means 305 starting with data with the highest priority, followed by data with a lower priority is preferred to a construction in which spooling is performed to the spool means 305 in the order of inputting (that is in the order of data reception).

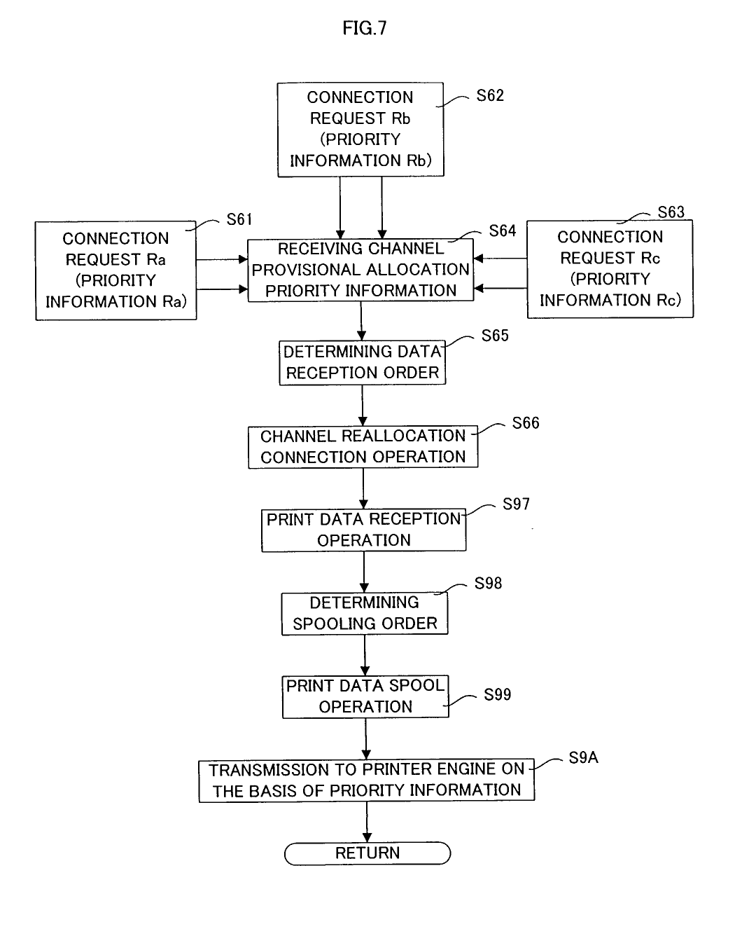

Therefore, after a connection operation starts as described above, (FIG. 5, step S66), the order of spooling may be determined on the basis of priority information (FIG. 7, step S97→step S98). By doing so, since spooling is performed sequentially in the decreasing order of data priorities, printing is sequentially performed starting with data with the highest priority, followed by data with a lower priority (FIG. 7, step S99→step S9A).

In a case where the order of spooling is determined on the basis of priority information in such a manner, an operation to determine the order of data reception is not always necessary. That is, while in FIG. 7, a procedure is exemplified that after the order of data reception is determined on the basis of priority information, the order of spooling is further determined on the basis of priority information, the present invention is not limited thereto.

When a priority of a job relating to a new connection request is the highest, a job relating to the new connection request preferably assumes the first place in the order of processing. A change in the order of a job in such a way is realized only by changing at least one of the order of data reception, a data transfer rate and the order of data spooling as is clear from the above description as well.

When data attached with the highest priority information “00” is received somewhere during the course where data attached with one of priority information “01”, “10” and “11” is already spooling, a spool operation currently in process is halted. Data attached with the highest priority “00” is spooled and transmitted to the printer engine 307 taking precedence over the others.

In such circumstances, data that has been spooled may also be discarded in the increasing order of priority starting with data with the lowest priority, followed by data with a higher priority. By doing so, a sufficient memory capacity can be secured for spooling data with the highest priority information “00”.

Note that while in the above description, there are exemplified two digit numeral strings “00”, “01”, “10” and “11” as priority information, a form of priority information is not limited thereto. That is, information other than a two digit figure string realizes a similar effect as far as the information can determines a priority.

In addition, in the above description, it is a precondition that data is attached with priority information in advance and no reference is made to when priority information is attached in what situation, which will be described later.

Third Embodiment

In a case where a great amount of data is received, there is a chance that all the data cannot be spooled. Therefore, in order to be able to perform optimal printing in any unfavorable case, the following means is adopted in this embodiment.

It is a precondition below that capacity information of data is attached to a connection request and description of the capacity information is given using a symbol “DV” indicating the capacity information. In addition, a residual capacity of a spool memory is indicated by a symbol “SPMR”.

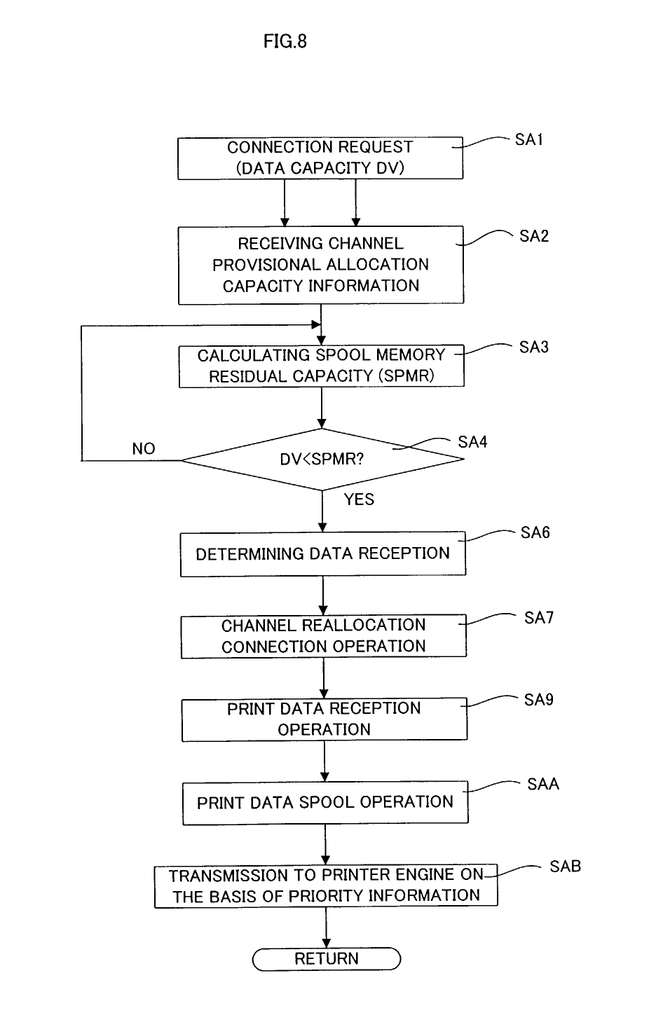

At first, the connection means 301 having received a connection request from external equipment allocates a channel to the external equipment provisionally. Then, the connection means 301 reads capacity information DV attached to the connection request to give the capacity information DV to the comparison means 301a (FIG. 8, step SA1→step SA2).

With the capacity information DV given, when the comparison means 301a asks the spool means 305 about a usage state of the spool memory, the spools means 305 having received the inquiry returns spooled data capacity to the comparison means 301a. Then, the comparison means 301a calculates a residual capacity SPMR of the spool memory on the basis of the data capacity and thereafter, compares the residual capacity SPRM and the above described capacity information DV with each other to give a result of the comparison to the connection means 301 (FIG. 8, step SA3).

Here in a case where the residual capacity SPMR is larger than the capacity information DV, the comparison means 301 receives the data (FIG. 8, Yes in step SA4→step SA6), and similar to the second embodiment, there is performed a process from a channel reallocation connection operation to a transmission operation to the printer engine (FIG. 8, step SA7→step SA8→step SA9→step SAA→step SAB). Contrary to this in a case where the residual capacity SPMR is smaller than the capacity information DV, the data is not received till a necessary capacity for spooling is obtained. (No in step SA4→step SA3→, No in step SA4→step SA3 . . . ).

Even in a case where the residual capacity SPMR is smaller than the capacity information DV, the data may be received if the difference is small. That is a timing at which a difference in magnitude between the residual capacity SPMR and the capacity information DV is checked is prior to a timing at which spooling is actually performed. When such circumstances are considered, even data whose capacity is a little in excess of the residual capacity SPMR, there is a chance to receive all of the data when spooling is performed.

Whether or not reception of data is necessary may be determined giving consideration to not only a difference in magnitude between a residual capacity SPMR and capacity information DV but also priority information. For example, even in a case where the residual capacity SPMR is larger than the capacity information DV, determination not to receive data may be made when a capacity of the data is larger than a prescribed value and a priority thereof is low. This is because with such a determination made, a state capable of receiving subsequent data with smoothness can be established.

In this embodiment, as described above, since the order of spooling is determined on the basis of not only priority information but also capacity information of data, more optimal printing can be ensured.

Fourth Embodiment

A connection request relating a job with a low priority, as described above, has a chance not to be accepted by the image output device 3. Since one-sided rejection on the side of the image output device 3 is severe on a requester; however, the following means is adopted in this embodiment.

That is, the comparison means 301a compares priority information A attached to a connection request and priority information B currently in process with each other to give a result of the comparison to the connection means 301. The “priority information currently in process” is priority information of data is currently processed in the image output device 3.

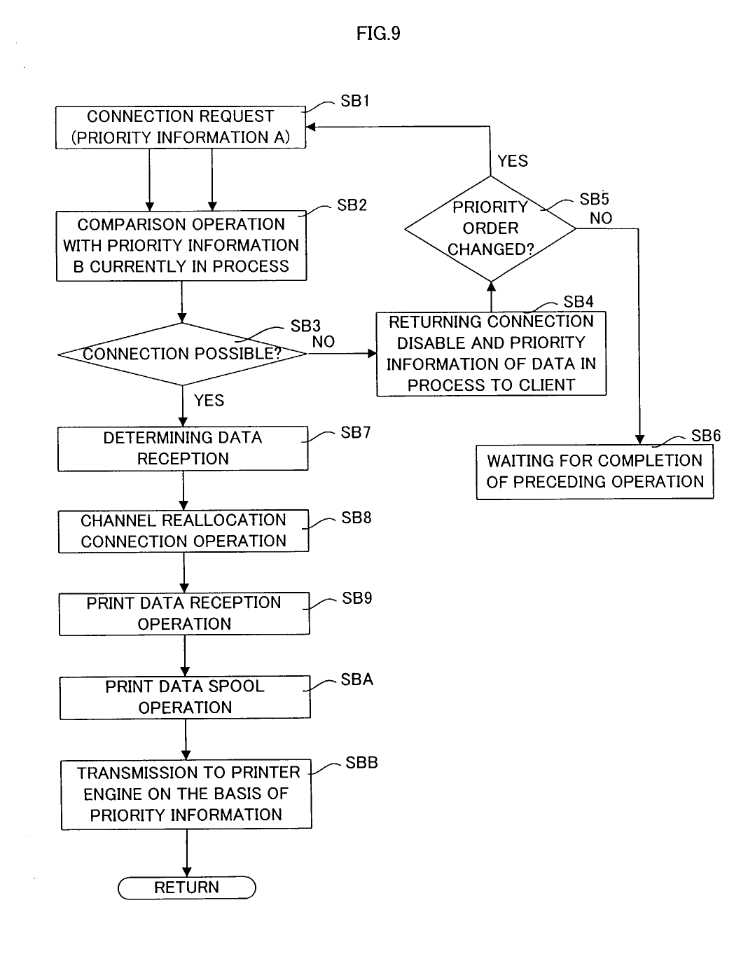

With the comparison result given, the connection means 301 determines whether or not the connection can be made on the basis of the comparison result, that is whether or not the connection request is to be accepted (FIG. 9, step SB1→step SB2→step SB3). In a case where priority information A attached to the connection request is higher than priority information B currently in process, the data is received (FIG. 9, yes in step SB3→step SB7) and similar to the second embodiment, a process from a channel reallocation connection operation to a transmission operation to the printer engine (FIG. 9, step SB7→step SB8→step SB9→step SBA→step SBB). Contrary to this, in a case where it is found that priority information A attached to the connection request is lower than priority information B currently in process, a signal indicating connection disable is returned to external equipment (a client) having issued the connection request (FIG. 9, No in step SB3→step SB4).

In a case where the connection disable signal is returned as described above, it is preferable that priority information B currently in process is preferably returned together with the connection disable signal. By doing so, a user of the external equipment having received the connection disable signal can determine with ease whether or not a change of priority information is necessary.

That is, the external equipment received the connection disable signal displays a message such as “Data with a priority B is now in process. Is a priority order changed?” on display means thereof. By doing so, an inquiry can be made of the user whether or not a change of the priority information A is necessary (FIG. 9, step SB5).

If the user issues an instruction of not changing the priority order in response to the inquiry, the data enters a state of waiting for completion of the preceding operation (FIG. 9, No in step SB5→step SB6). On the other hand, if the user issues an instruction of changing the priority order, a new connection request is issued to the image output device 3 from the external equipment (FIG. 9, Yes in step SB5→step SB1).

The connection request newly reissued this way must be attached with priority information higher than B. Therefore, if it is determined whether or not the connection request should be accepted, the determination is affirmative and the connection means 301, according to the affirmative determination, determines reception of the data (FIG. 9, steps SB1→step SB2→Yes in step SB3→step SB7).

In this embodiment, as described above, priority information can be changed when a necessity arises. Such a construction is of great convenience especially in a case where plural equipment pieces are used in the home of a single user.

That is, description will be given of an example of a television set and a portable telephone as equipment used in home; it is preferable that data from the television set is printed with a priority over data from the portable telephone. This is because generally, a television set has a usage frequency very much higher than a portable telephone.

Therefore, in such an environment, default setting is made such that priority information “10” is attached to a print request from a portable telephone and priority information “01” is attached to a print request from a television set. With such default setting, data from a television set is printed with precedence over data from a portable telephone.

A case also arises, however, where data from a portable telephone is desired to be printed with precedence over data from a television set. For example, since an emergency report arrives at a portable telephone, a case arise where contents thereof is printed.

In such a case, priority attached to data from a portable telephone has only to be changed from “10” to “00”. By doing so, data from a portable telephone is printed with precedence over data from a television set. In addition, in this case, a great effect is exercised that since the highest priority information “00” is attached, the data is immediately printed even if many of data is in a state of waiting for completion of the preceding operation.

While in the above description, priority information is set as a default at external equipment, the present invention is not limited thereto. That is, it is possible to designate priority information from input means each time a print instruction is issued from external equipment. It is natural that priority information designated here is to be transmitted to the image output device 3 attaching to the connection request.

While in the above description, priority information is determined for each piece of external equipment as a unit, the present invention is not limited thereto. That is, in a case where plural users share an external equipment piece, priority information is also sometimes preferably determined for each user as a unit.

For example, in a case where parents and their children share equipment in home, data for which a parent issues a print request preferably takes precedence over data for which a child issues a print request. In this case, a user ID and a password of his or her own are inputted on issuance of a print request.

While in the above description, priority information is attached on the side of external equipment, the present invention is not limited thereto. That is, while data, which is an object for printing, is as described above in an aspect that the data is generated on the basis of contents received from the internet or the like by external equipment, it is also possible for an original transmitter of contents to attach priority information thereto in advance.

Though in the above description, no special reference is made, the image output device 3 is equipped with a correspondence table (not shown). The correspondence table is a table in which information unique to each external equipment piece or each data is related with priority information indicating a priority of a job in advance.

When the connection means (change means) 301 receives a change request for priority information as described above from external equipment, contents of a correspondence table is changed on the basis of contents of the change request. Detailed description of a technique updating contents of the table in such a manner is omitted here since the technique itself has been publicly known.

Needless to say that a timing at which the connection means (change means) 301 changes contents of a correspondence table is not limited to when the connection means 301 receives a change request from external equipment. For example, when the connection means (change means) 301 receives a result of the checking from the check means 303, the connection means (change means) 301 may change contents of the correspondence table on the basis of the check results.

Fifth Embodiment

While in the above fourth embodiment, a scene where the present invention is applied to an environment in home is imagined and description thereof is given, the present invention can also be applied in an environment such as a convenience store, for example. Even if such a difference in environment exists, the effect of the present invention can be attained with a similar construction to the above description. As described below, however, convenience is increased by adoption of a construction different from the above construction by a bit.

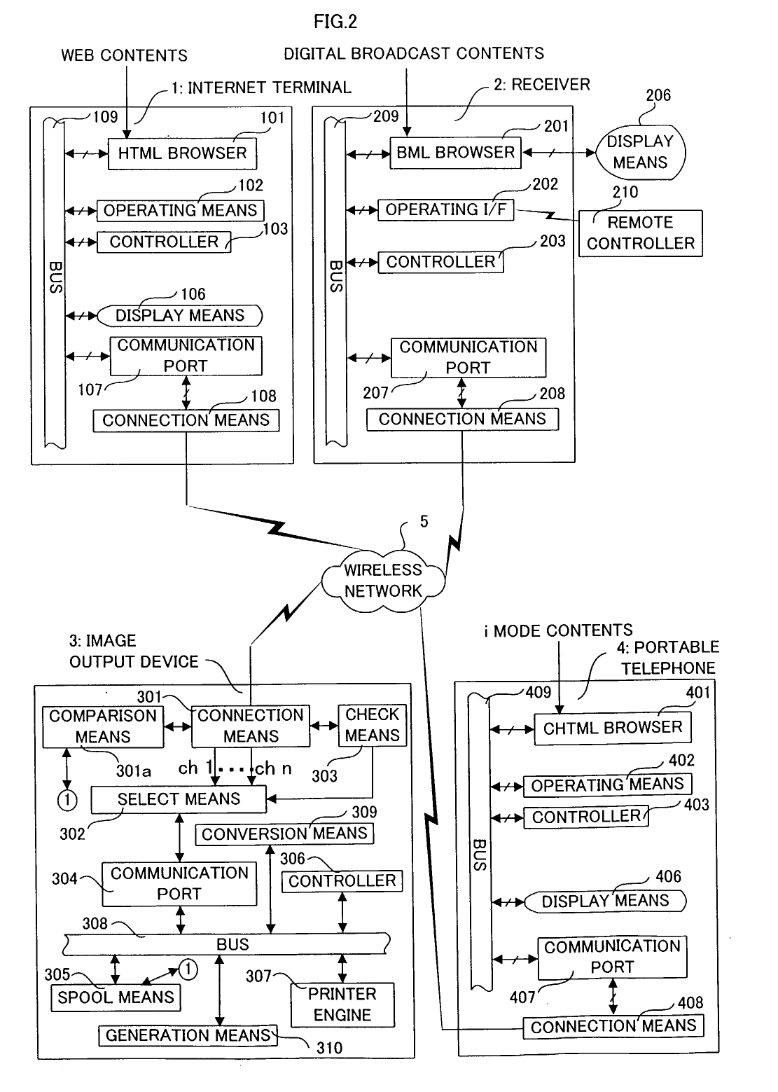

That is, the above description exemplifies that a construction is provided with a conversion means for changing a format of data into a prescribed one and generation means for generating data for printing on the basis of data converted by the conversion means on the side of the external equipment. In contrast to this, in this embodiment, as shown in FIG. 2, a construction is adopted in which the conversion means and the generation means are provided on the side of the image output device 3.

With such a construction adopted, for example, in a case where a user of a portable telephone newly subscribes to the system, no necessity arises for providing special functions (conversion means and generation means) to the portable telephone. That is, if such special functions are provided on the side of the image output device 3, the effect of the present invention can be attained using external equipment with standard specifications, so an advantage can be enjoyed that can increase the number of subscribers to the system.

With such a change in construction, fundamental functions of the system in the entirety are not different from those of the first to fourth embodiments though a difference arises according to whether operations of conversion and print data generation are performed on the side of external equipment or on the side of the image output device 3.

In a scene where the system is applied to a convenience store or the like in such a way, a necessity arises for authenticating whether a user in consideration is a regular member or not. Therefore, in such a scene, provided on the side of external equipment is transmission means (not shown) transmitting information including even identification information of the user upon issuance of a new connection request to the image output device 3.

While here, user identification information is transmitted from external equipment to the image output device 3, information for identify an external equipment piece such as a machine ID may be transmitted instead of the user identification information.

The identification information of a user or an external equipment piece described here is information of a nature similar to the connection right information and an operation of the image output device 3 when receiving the identification information pieces is similar to when receiving the connection right information. Therefore, detailed description of the operation will not repeated.

In a scene where the system is applied to a convenience store or the like, a method to attach priority information to a print request may be changeable according to a way of payment of a charged fee for the system as described below.

A method for attaching priority information may be changed according to a difference in payment system of whether cashless automatic settlement is adopted (payment by card via an internet terminal, a portable telephone with an i mode function or the like) or payment is performed in the order of reception at a cash register in a store. That is, when a user transmits a print request from outside of a convenience store, the payment is of automatic settlement, so priority information is preferably attached in the order of acceptance by the image output device 3 installed at the convenience store. On the other hand, a print request is transmitted by a user in a convenience store, priority information is preferably attached in the order of reception at a cash register in the convenience store.

A way for attaching priority information may be changed according to a difference in person in charge of payment of whether a user pays a charged fee for usage of the system (and a charged fee for the contents), or a contents provider or a commercial sponsor pays the fee. That is, a case where a user pays a charged fee for usage of the system (and a charged fee for the contents) preferably has attachment of priority information higher than a case where a commercial sponsor or a contents provider pays the charged fee.

To be added in the last stage of the specification, while in the above description, there is exemplified only a construction in which the image output device 3 prints data, the image output device 3 is not limited to a printer. That is, the present invention can also be applied to an image output device (for example, a display or a facsimile) other than a printer.

In the present invention, as described above, print data from an external equipment piece having issued a new connection request can take a priority in handling over print data from an external equipment piece connected through a channel with a small usage frequency.

Furthermore, in the present invention, since the order of data reception is determined on the basis of priority information attached to a connection request, printing is performed in the decreasing order of priority starting with the highest priority.

Moreover, by determining the order of spooling on the basis of not only priority information but also capacity information of data, more optimal printing can be ensured.

Still moreover, according to the present invention, priority information can be changed according a need. Such a construction is of great convenience especially in a scene where a single user uses plural equipment pieces in home.

Needless to say that in an environment such as a convenience store as well, the present invention can be applied.

What is claimed is:

1. An image output device outputting data from external equipment establishing multichannel connection therewith, comprising:
check means for checking an existing connection state when receiving a new connection request from an external equipment piece; and
connection means for securing a connection channel with said external equipment piece having issued said new connection request on the basis of a result of the checking attained by said check means.

2. The image output device according to claim 1, wherein
said connection means secures said connection channel with said external equipment piece having issued said new connection request by cutting off connection of a channel having a small usage frequency, or by alternatively reducing a data transfer rate of a channel having a small usage frequency.

3. An image output device outputting data from an external equipment establishing multichannel connection therewith, comprising:
comparison means for comparing a priority of a job relating to a first channel and a priority of a job relating to a second channel with each other when receiving a new connection request from an external equipment piece; and
connection means for changing the order of jobs on the basis of a result of the comparison obtained by said comparison means.

4. The image output device according to claim 3, wherein
said connection means changes at least one of the order of data reception, a data transfer rate and the order of data spooling on the basis of a result of said comparison obtained by said comparison means.

5. The image output device according to claim 3, wherein
when a priority of a job relating to said new connection request is the highest, said connection means causes a job relating to said new connection request to assume the first place in the order of processing.

6. The image output device according to claim 3, wherein
when a priority of a job relating to an existing connection request is lower than a priority of a job relating to said new connection request, said connection means discards data relating to said existing connection request.

7. The image output device according to claim 3, wherein
when a capacity necessary for spooling data relating to said new connection request is obtained by discarding data sequentially in the increasing order starting with data relating to a job with the lowest priority, said connection means starts reception of data relating to said new connection request.

8. The image output device according to claim 3, wherein
when a capacity necessary for spooling data relating to said new connection request is not obtained even by discarding data sequentially in the increasing order starting with data relating to a job with the lowest priority, said connection means starts reception of data relating to said new connection request if a shortage amount is equal to or less than a prescribed amount.

9. The image output device according to claim 3, wherein
said connection means, when not accepting said new connection request, makes an inquiry of said external equipment piece whether or not a change of a priority of a job relating to said connection request is necessary.

10. The image output device according to claim 3, wherein
said connection means, when not accepting said new connection request, makes an inquiry of said external equipment piece whether or not a change of a priority of a job relating to said connection request is necessary showing a priority of a job currently in process.

11. The image output device according to claim 3, wherein
a priority of said job is determined for each external equipment or each data as a unit.

12. An image output device outputting data from an external equipment establishing multichannel connection therewith, comprising:
a correspondence table in which information unique to each external equipment piece or each data is related with priority information indicating a priority of a job in advance; and
change means for changing contents of said correspondence table.

13. The image output device according to claim 12, wherein
said change means, when receiving a change request of said priority information from an external equipment piece, changes contents of said correspondence table on the basis of contents of said change request.

14. The image output device according to claim 12, further comprising:
check means for checking an existing connection state, wherein
said change means changes contents of said correspondence table on the basis of a result of the checking attained by said check means.

15. The image output device according to any of claims of 1, 3 and 12, which prints data from external equipment establishing multichannel connection therewith.

16. A connecting destination selecting method for an image output device outputting data from external equipment establishing multichannel connection therewith, comprising:
a check operation for checking an existing connection state when a new connection request is received from an external equipment piece; and
a connection operation for securing a connection channel with said external equipment piece having issued said new connection request on the basis of a result of said check operation.

17. A connecting destination selecting method for an image output device outputting data from external equipment establishing multichannel connection therewith, comprising:
a comparison operation for comparing a priority of a job relating to a first channel and a priority of a job relating to a second channel with each other when a new connection request is received from an external equipment piece;
a connection operation for changing the order of jobs on the basis of a result of said comparison operation.

18. An image output system equipped with an image output device outputting data from external equipment establishing multichannel connection therewith, comprising:
check means for checking an existing connection state when receiving a new connection request from an external equipment piece; and
connection means securing a connection channel with said external equipment piece having issued said new connection request on the basis of a result of the checking.

19. An image output system equipped with an image output device outputting data from external equipment establishing multichannel connection therewith, comprising:
comparison means for comparing a priority of a job relating to a first channel and a priority of a job relating to a second channel with each other when receiving a new connection request from an external equipment piece;
connection means for changing the order of jobs on the basis of a result of the comparison.

20. A program for causing a computer to execute:
a check operation for checking an existing connection state when a new connection request is received from an external equipment piece; and
a connection operation for securing a connection channel with said external equipment piece having issued said new connection request on the basis of a result of said check operation.

21. A program for causing a computer to execute:
a comparison operation for comparing a priority of a job relating to a first channel and a priority of a job relating to a second channel with each other when a new connection request is received from an external equipment piece; and
a connection operation for changing the order of jobs on the basis of a result of said comparison operation.
